(19) United States
(12) Patent Application Publication
(10) Pub. No.: US 2023/0004351 A1
(43) Pub. Date: Jan. 5, 2023

(54) METHOD AND DEVICE FOR ADDITIVE CODING OF SIGNALS IN ORDER TO IMPLEMENT DIGITAL MAC OPERATIONS WITH DYNAMIC PRECISION

(71) Applicant: COMMISSARIAT A L'ENERGIE ATOMIQUE ET AUX ENERGIES ALTERNATIVES, PARIS (FR)

(72) Inventors: Johannes Christian THIELE, GIF SUR YVETTE (FR); Olivier BICHLER, VIEILLE EGLISE EN YVELINES (FR); Vincent LORRAIN, SAULX-LES-CHARTREUX (FR)

(21) Appl. No.: 17/784,656

(22) PCT Filed: Dec. 10, 2020
(86) PCT No.: PCT/EP2020/085417

§ 371 Date: Jun. 12, 2022

(30) Foreign Application Priority Data
Dec. 18, 2019 (FR) FR1914706

(51) Int. Cl. G06F 7/544; G06N 3/08

(52) U.S. Cl. CPC G06F 7/5443; G06N 3/084

(57) ABSTRACT

A computer-implemented method is provided for coding a digital signal quantized on a given number N_{d} of bits and intended to be processed by a digital computing system, the signal being coded on a predetermined number Nₚ of bits which is strictly less than N_{d}, the method including the steps of: receiving a digital signal composed of a plurality of samples, decomposing each sample into a sum of k maximum values which are equal to 2^{N}P−1 and a residual value, with k being a positive or zero integer, successively transmitting the values obtained after decomposition to an integration unit for carrying out a MAC operation between the sample and a weighting coefficient.

The invention relates to the field of computing architectures for machine learning models, in particular artificial neural networks, and bears on a method and a device for coding and integrating digital signals with dynamic precision adapted to signals propagated in an artificial neural network.

More generally, the invention is applicable to any computing architecture implementing operations of multiply-accumulate (MAC) type.

Artificial neural networks are computational models imitating the operation of biological neural networks. Artificial neural networks comprise neurons which are interconnected by synapses, which are conventionally implemented by digital memories. The synapses may also be implemented by resistive components the conductance of which varies depending on the voltage applied across their terminals. Artificial neural networks are used in various fields of (visual, audio or other) signal processing, such as, for example, in the field of image classification or image recognition.

A general problem for architectures of computers implementing an artificial neural network relates to the overall energy consumption of the circuit creating the network.

The basic operation implemented by an artificial neuron is a multiply-accumulate (MAC) operation. According to the number of neurons per layer and of layers of neurons which the network comprises, the number of MAC operations per unit of time needed for real-time operation becomes restrictive.

There is therefore a need to develop computing architectures optimized for neural networks which make it possible to limit the number of MAC operations without degrading either the performance of the algorithms implemented by the network or the precision of the computations.

The Applicant's international application WO 2016/050595 describes a signal coding method making it possible to simplify the implementation of the MAC operator.

One drawback of this method is that it does not make it possible to take into account the nature of the signals propagated in a digital computer implementing a learning function such as an artificial neural network.

Specifically, when the dynamic range of the signals is very variable, quantization on a fixed number of bits of all the samples leads to sub-optimal sizing of the computing operators, in particular of the MAC operators. This has the effect of increasing the overall energy consumption of the computer.

The invention proposes a coding method with dynamic precision which makes it possible to take into account the nature of the signals to be coded, in particular the variability of the dynamic range of the values of the signals.

Due to its dynamic aspect, the invention makes it possible to optimize the coding of the signals propagated in a neural network so as to limit the number and the complexity of MAC operations carried out and thus limit the energy consumption of the circuit or computer creating the network.

One subject of the invention is a computer-implemented method for coding a digital signal quantized on a given number Nd of bits and intended to be processed by a digital computing system, the signal being coded on a predetermined number Nₚ of bits which is strictly less than N_{d}, the method comprising the steps of:
Receiving a digital signal composed of a plurality of samples,
Decomposing each sample into a sum of k maximum values which are equal to 2^{Np}−1 and a residual value, with k being a positive or zero integer,
Successively transmitting the values obtained after decomposition to an integration unit for carrying out a MAC operation between the sample and a weighting coefficient.

According to one particular variant, the method comprises a step of determining the size Nₚ of the coded signal depending on a statistical distribution of the values of the digital signal.

According to one particular aspect of the invention, the size Nₚ of the coded signal is parameterized so as to minimize the energy consumption of a digital computing system in which the processed signals are coded by means of said coding method.

According to one particular aspect of the invention, the energy consumption is estimated by simulation or on the basis of an empirical model.

According to one particular aspect of the invention, the digital computing system implements an artificial neural network.

According to one particular aspect of the invention, the size Nₚ of the coded signal is parameterized independently for each layer of the artificial neural network.

Another subject of the invention is a coding device, comprising a coder configured to execute the coding method according to the invention.

Another subject of the invention is an integration device, configured to carry out a multiply-accumulate (MAC) operation between a first number coded by means of the coding method according to the invention and a weighting coefficient, the device comprising a multiplier for multiplying the weighting coefficient by the coded number, an adder and an accumulation register for accumulating the output signal of the multiplier.

Another subject of the invention is an artificial neuron, implemented by a digital computing system, comprising an integration device according to the invention, for carrying out a multiply-accumulate (MAC) operation between a received signal and a synaptic coefficient, and a coding device according to the invention for coding the output signal of the integration device, the artificial neuron being configured to propagate the coded signal to another artificial neuron.

Another subject of the invention is an artificial neuron, implemented by a computer, comprising an integration device according to the invention for carrying out a multiply-accumulate (MAC) operation between an error signal received from another artificial neuron and a synaptic coefficient, a local error computing module configured to compute a local error signal on the basis of the output signal of the integration device and a coding device according to the invention for coding the local error signal, the artificial neuron being configured to back-propagate the local error signal to another artificial neuron.

Another subject of the invention is an artificial neural network comprising a plurality of artificial neurons according to the invention.

Other features and advantages of the present invention will become more clearly apparent upon reading the following description with reference to the following appended drawings.

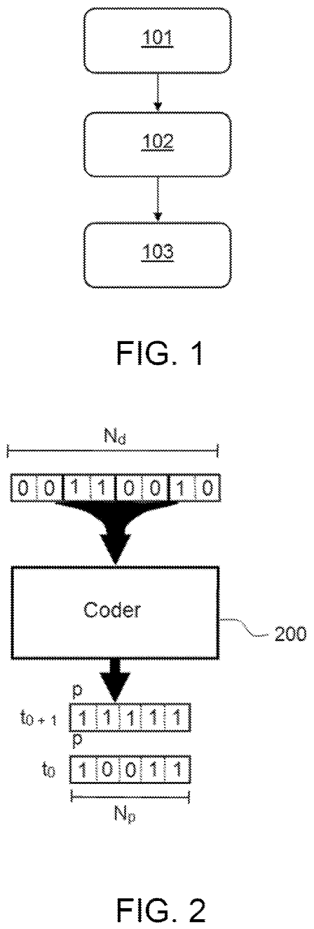

FIG. 1 shows a flowchart illustrating the steps for implementing the coding method according to the invention,

FIG. 2 shows a diagram of a coder according to one embodiment of the invention,

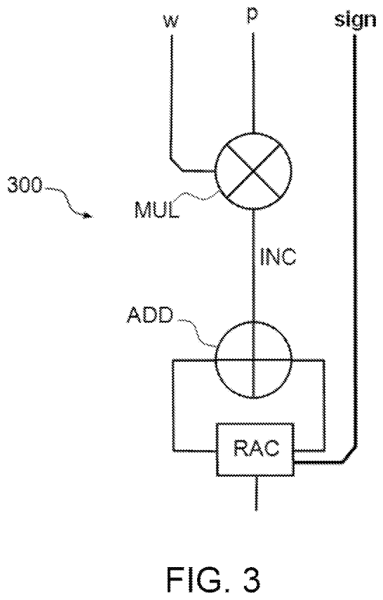

FIG. 3 shows a diagram of an integration module for carrying out an operation of MAC type for numbers quantized via the coding method of FIG. 1,

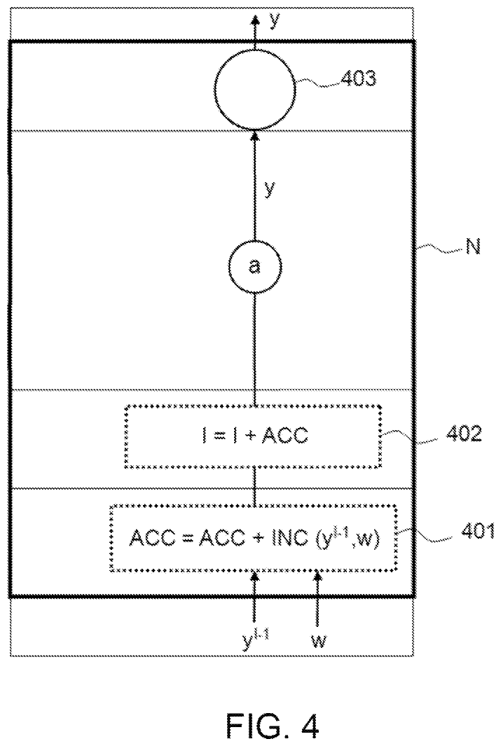

FIG. 4 shows a block diagram of an exemplary artificial neuron comprising an integration module of the type of FIG. 3 for operation during a data propagation phase,

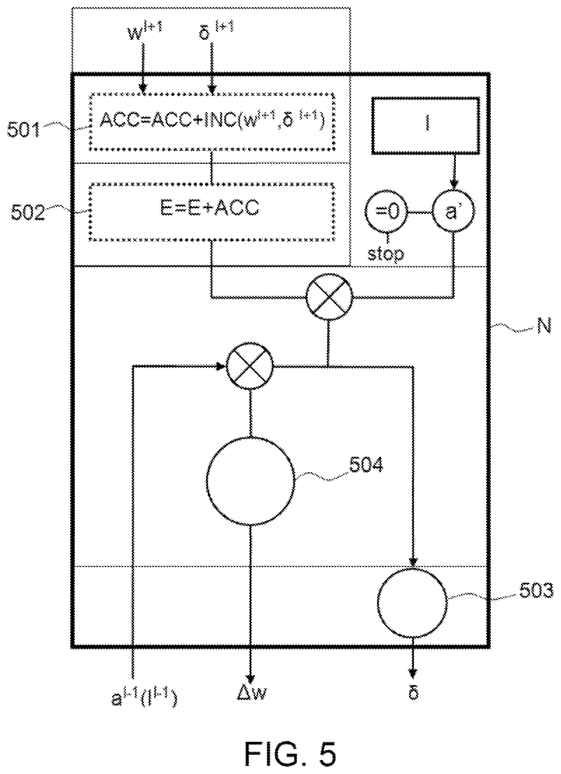

FIG. 5 shows a block diagram of an exemplary artificial neuron comprising an integration module of the type of FIG. 3 for operation during a data back-propagation phase.

FIG. 1 shows, on a flowchart, the steps for implementing a coding method according to one embodiment of the invention.

One objective of the method is to code a number quantized on N_{d} bits as a group of values which can be transmitted (or propagated) separately in the form of events.

To this end, the first step 101 of the method consists in receiving a number y quantized on N_{d} bits, N_{d} being an integer. The number y is, typically, a quantized sample of a signal, for example an image signal, an audio signal or a data signal intrinsically comprising a piece of information. For a conventional computing architecture, the number Nd is typically equal to 8, 16, 32 or 64 bits. It is notably sized depending on the dynamic range of the signal, that is to say the difference between the minimum value of a sample of the signal and its maximum value. In order not to introduce quantization noise, the number N_{d} is generally chosen so as to take into account this dynamic range in order not to saturate or clip the high or low values of the samples of the signal. This can lead to choosing a high value for N_{d}, which leads to a problem of oversizing of the computing operators which have to carry out operations on samples thus quantized.

The invention therefore aims to propose a method for coding the signal which makes it possible to adapt the size (in number of bits) of the samples transmitted depending on their real value so as to be able to carry out operations on quantized samples with a lower number of bits.

In a second step 102, the number Nₚ of bits on which the coded samples to be transmitted are quantized is chosen. Nₚ is less than N_{b}.

The number y is then decomposed in the following form:

y=k·(2^{N}^{ₚ}−1)+vᵣ=k·vₘₐₓ+vᵣ [Math. 1]

k is a positive or zero integer, vᵣ is a residual value and vₘₐₓ is the maximum value of a number quantized on Nₚ bits.

The sample y is then coded by the succession of the k values vₘₐₓ and the residual value vᵣ which are transmitted successively.

For example, if y=50 and Nₚ=4, y is coded by transmitting the successive values {15},{15},{15},{5}={1111},{1111},{1111},{0101}.

If y=50 and Nₚ=5, y is coded by transmitting the successive values {31},{19}={11111},{10011}.

Upon reception, the end or the beginning of a new sample can be identified by the reception of a value which is different from the maximum value vₘₐₓ. The next value received then corresponds to a new sample.

In a final step 103, the coded signals are transmitted, for example via a data bus of appropriate size, to a MAC operator with a view to carrying out a multiply-accumulate operation.

The proposed coding method makes it possible to reduce the size of the operators (which are designed to carry out operations on Nₚ bits) while at the same time making it possible to preserve the whole dynamic range of the signals. Specifically, samples with a high value (greater than vₘₐₓ) are coded by several successive values, while samples with a low value (less than vₘₐₓ) are transmitted directly.

Moreover, this method does not require addressing in order to identify the coded values belonging to the same sample as a value which is less than vₘₐₓ indicates the end or the beginning of a sample.

FIG. 2 shows, in schematic form, an exemplary coder 200 configured to code an input value y by applying the method described in FIG. 1. In FIG. 2, the non-limiting digital example for y=50 and Nₚ=5 has been taken.

The values {11111} and {10011} are transmitted at two successive instants. The order of transmission is chosen by convention.

One advantage of the proposed coding method is that it makes it possible to limit the size of the coded data transmitted to Nₚ bits. Another advantage lies in its dynamic aspect, because the parameter Nₚ can be adapted according to the nature of the data to be coded or depending on the constraints on the sizing of the operators used to carry out computations on the coded data.

FIG. 3 schematically shows an integration module 300 configured to carry out an operation of multiply-add type or MAC operation. The integration module 300 described in FIG. 3 is optimized for processing data coded via the method according to the invention. Typically, the integration module 300 implements a MAC operation between an input datum p coded via the coding method according to the invention and a weighting coefficient w which corresponds to a parameter learned by a machine learning model. The coefficient w corresponds, for example, to a synaptic weight in an artificial neural network.

An integration module 300 of the type described in FIG. 3 can be duplicated in order to carry out MAC operations in parallel between several input values p and several coefficients w.

Alternatively, one and the same integration module can be activated sequentially in order to carry out several successive MAC operations.

The integration module 300 comprises a multiplier MUL, an adder ADD and an accumulation register RAC.

When the integration module 300 receives a coded value p, the value saved in the accumulation register RAC is incremented by the product INC=w·p of the value p and the weighting coefficient w.

When a new sample is indicated, for example by the reception of a value which is different from vₘₐₓ, the register RAC is reset.

The operators MUL, ADD of the device are sized for numbers quantized on Nₚ bits, which makes it possible to reduce the overall complexity of the device.

The size of the register RAC must be greater than the sum of the maximum sizes of the values w and p. Typically it will be of the size N_{d}+N_{w}, which is the maximum size of a MAC operation between words of sizes N_{d} and N_{w}.

In one variant embodiment, when the numbers are represented in signed notation, a sign management module (not shown in detail in FIG. 3) is also needed.

The integration module 300 according to the invention can be advantageously used to implement an artificial neural network as illustrated in FIGS. 4 and 5.

Typically, the function implemented by a machine learning model consists of an integration of the signals received as input and weighted by coefficients.

In the particular case of an artificial neural network, the coefficients are called synaptic weights and the weighted sum is followed by the application of an activation function a which, depending on the result of the integration, generates a signal to be propagated as output from the neuron.

Thus, the artificial neuron N comprises a first integration module 401 of the type of FIG. 3 for carrying out the product y^{l-1}·w with y^{l-1} being a value coded via the method according to the invention in the form of several events successively propagated between two neurons and w being the value of a synaptic weight. A second conventional integration module 402 is then used to integrate the products y^{l-1}·w over time.

Without departing from the scope of the invention, an artificial neuron N can comprise several integration modules for carrying out MAC operations in parallel for several input data and weighting coefficients.

The activation function a is, for example, defined by the generation of a signal when the integration of the received signals is completed. The activation signal is then coded via a coder 403 according to the invention (as described in FIG. 2), which codes the value as several events which are propagated successively to one or more other neurons.

More generally, the output value of the activation function a^{I} of a neuron of a layer of index I is given by the following relationship:

[Math. 1]

yᵢ^{l}=a^{l}(Σⱼyⱼ^{l-1} wᵢⱼ^{l}+bᵢ^{l})=a^{l}(Iᵢ^{l}) (1)

Iᵢ^{l} is the output value of the second integration module 402.

bᵢ^{l} represents a bias value which is the initial value of the accumulator in the second integration module 402.

wᵢⱼ^{l} represents a synaptic coefficient.

The output value yᵢ^{l} is then coded via a coder 403 according to the invention (as described in FIG. 2), which codes the value yⱼ^{l} as several events which are propagated successively to one or more other neurons.

The various operations implemented successively in a neuron N can be carried out at different rates, that is to say with different time scales or clocks. Typically, the first integration device 401 operates at a faster rate than the second integration device 402, which itself operates at a faster rate than the operator carrying out the activation function.

In the case where the two integration devices 401, 402 operate at the same rate, a single integration device is used instead of two. In general, according to the chosen hardware implementation, the number of accumulators used varies.

In a similar way to what was described above, the error signals back-propagated during the back-propagation phase can also be coded by means of the coding method according to the invention. In this case, an integration module according to the invention is implemented in each neuron for carrying out the weighting of the coded error signals received with synaptic coefficients as illustrated in FIG. 5, which shows an artificial neuron configured to process and back-propagate error signals from a layer l+1 to a layer l.

In the back-propagation phase, the error computation δᵢ^{l} is implemented according to the following equation:

[Math. 2]

δᵢ^{l}=a′^{l}(Iᵢ^{l}) Eᵢ^{l}, Eᵢ^{l}=Σₖ δₖ^{l+1} wₖᵢ^{l+1} (2)

a′^{l}(Iᵢ^{l}) is the value of the derivative of the activation function.

The neuron described in FIG. 5 comprises a first integration module 501 of the type of FIG. 3 for carrying out the computation of the product δₖ^{l+1} wₖᵢ^{l+1}, with δₖ^{l+1} being the error signal received from a neuron of the layer l+1 and coded by means of the coding method according to the invention and wₖᵢ^{l+1} being the value of a synaptic coefficient.

A second conventional integration module 502 is then used to carry out the integration of the results of the first module 501 over time.

The neuron N comprises other specific operators needed to compute a local error δᵢ^{l} which is then coded via a coder 503 according to the invention, which codes the error in the form of several events which are then back-propagated to the previous layer l−1.

The neuron N also comprises, moreover, a module for updating the synaptic weights 504 depending on the computed local error.

The various operators of the neuron can operate at different rates or time scales. In particular, the first integration module 501 operates at the fastest rate. The second integration module 502 operates at a slower rate than the first module 501. The operators used to compute the local error operate at a slower rate than the second module 502.

In the case where the two integration modules 501, 502 operate at the same rate, a single integration module is used instead of two. In general, according to the chosen hardware implementation, the number of accumulators used varies.

The invention proposes a means for adapting the computing operators of a digital computing architecture depending on the received data. It is particularly advantageous for architectures implementing machine learning models, in which the distribution of the data to be processed varies greatly according to the received inputs.

The invention notably has advantages when the propagated signals comprise a large number of low values or, more generally, when the signal has a wide dynamic range with a large variation in values. Specifically, in this case, the low values can be quantized directly on a limited number of bits, while the higher values are coded by several successive events, each quantized on the same number of bits.

Statistically, only 50% of the bits are zero when random binary data are considered. In contrast, the data propagated within a machine learning model have a large number of low values.

This property is explained notably by the fact that the data propagated by a machine learning model with several processing layers, such as a neural network, convey information which is concentrated, gradually during propagation, toward a small number of neurons. As a result, the values propagated to the other neurons are close to 0 or generally low.

One conventional approach to taking into account this particular property of the signals consists in coding all the values on a low number of bits (for example 8 bits). However, this approach has the drawback of having a large impact for values which exceed the maximum quantization value (for example 2⁸−1). Specifically, these values are clipped at the maximum value, which leads to losses of precision for the values which convey the most information.

This approach is therefore not adapted to these types of machine learning models.

Another approach still consists in coding the values on a fixed number of bits, but while adjusting the dynamic range so as not to clip the maximum values. This second approach has the drawback of modifying the value of data with low values, which are very numerous.

Thus, the coding method according to the invention is particularly adapted to the statistical profile of the values propagated in a machine learning model, because it makes it possible to take into account the whole dynamic range of the values without, however, using a fixed high number of bits to quantize all the values. Thus, there is no loss of precision due to the quantization of the data, but the operators used for the implementation of a MAC operator can be sized to process data of lower size.

One of the advantages of the invention is that the size Nₚ of the coded samples is a parameter of the coding method.

This parameter can be optimized depending on the statistical properties of the data to be coded. This makes it possible to optimize the coding so as to optimize the overall energy consumption of the computer or circuit creating the machine learning model.

Specifically, the coding parameters influence the values which are propagated in the machine learning model and therefore the size of the operators carrying out the MAC operations.

By applying the invention, it is possible to parameterize the coding so as to minimize the number of binary operations carried out or, more generally, to minimize or optimize the resulting energy consumption.

A first approach to optimizing the coding parameters consists in simulating the behavior of a machine learning model for a set of training data and simulating its energy consumption depending on the number and size of the operations carried out. By varying the coding parameters for the same set of data, the parameters which make it possible to minimize energy consumption are sought.

A second approach consists in determining a mathematical model to express the energy consumed by the machine learning model or, more generally, the targeted computer, depending on the coding parameter Nₚ.

In the case of application of a neural network, the coding parameter Np may be different according to the layer of the network. Specifically, the statistical properties of the propagated values can depend on the layer of the network. Advancing through the layers, the information tends to be more concentrated toward a few particular neurons. In contrast, in the first layers, the distribution of the information depends on the input data of the neuron, it can be more random.

An exemplary mathematical model for a neural network is proposed below.

The energy E^{l} consumed by a layer of a network depends on the energy Eᵢₙₜ^{l}(Nₚ) consumed by the integration of an event (a received value) by a neuron and the energy E_{enc}^{l-1}(Nₚ) consumed by the coding of this event by the previous layer.

Thus, a model of the energy consumed by a layer can be formulated using the following relationship:

[Math. 3]

E^{l}=Nₕᵢₛₜ^{l-1}(Nₚ^{l})·(E_{enc}^{l-1}(Nₚ^{l})+Eᵢₙₜ^{l}(Nₚ^{l})·nᵢₙₜ^{l}) (3)

nᵢₙₜ^{l} is the number of neurons in the layer l.

Nₕᵢₛₜ^{l-1}(Nₚ^{l}) is the number of events transmitted by the layer l−1. This number depends on the coding parameter Nₚ^{l} and the distribution of the data.

On the basis of the model given by relationship (3), the value of Nₚ^{l} which makes it possible to minimize the energy E^{l} consumed is sought for each layer.

The functions Eᵢₙₜ^{l}(Nₚ^{l}) and E_{enc}^{l-1}(Nₚ^{l}) can be determined on the basis of empirical functions or models by means of simulations or on the basis of real measurements.

One advantage of the invention is that it makes it possible to parameterize the value of Nₚ^{l} independently for each layer l of the network, which makes it possible to finely take into account the statistical profile of the propagated data for each layer.

The invention can also be applied in order to optimize the coding of error values back-propagated during a gradient back-propagation phase. The coding parameters can be optimized independently for the propagation phase and the back-propagation phase.

In one variant embodiment of the invention, the activation values in the neural network can be constrained so as to favor a wider distribution of low values.

This property can be obtained by acting on the cost function implemented in the final layer of the network. By adding a term to this cost function which depends on the values of the propagated signals, large values in the cost function can be penalized and activations in the network can thus be constrained to lower values.

This property makes it possible to modify the statistical distribution of the activations and thus to improve the efficiency of the coding method.

The coding method according to the invention can be advantageously applied to the coding of data propagated in a computer implementing a machine learning function, for example an artificial neural network function for classifying data according to a learning function.

The coding method according to the invention can also be applied to the input data of the neural network, in other words the data produced as input to the first layer of the network. In this case, the statistical profile of the data is exploited in order to best code the information. For example, in the case of images, the data to be encoded can correspond to pixels of the image or groups of pixels or also to differences between pixels of two consecutive images in a sequence of images (video).

The computer according to the invention may be implemented using hardware and/or software components. The software elements may be available as a computer program product on a computer-readable medium, which medium may be electronic, magnetic, optical or electromagnetic. The hardware elements may be available, in full or in part, notably as application-specific integrated circuits (ASICs) and/or field-programmable gate arrays (FPGAs) and/or as neural circuits according to the invention or as a digital signal processor (DSP) and/or as a graphics processing unit (GPU), and/or as a microcontroller and/or as a general-purpose processor, for example. The computer CONV also comprises one or more memories, which may be registers, shift registers, a RAM memory, a ROM memory or any other type of memory adapted to implementing the invention.

1. A computer-implemented method for coding a digital signal composed of samples quantized on a given number N_{d} of bits and intended to be processed by a digital computing system, the signal being coded by means of samples quantized on a predetermined number Nₚ of bits which is strictly less than N_{d}, the method comprising the steps of:
receiving a digital signal composed of a plurality of samples,
decomposing each sample into a sum of k maximum values which are equal to 2^{N}^{ₚ}−1 and a residual value, with k being a positive or zero integer, and
successively transmitting the values obtained after decomposition to an integration unit for carrying out a MAC operation between the sample and a weighting coefficient.

2. The coding method as claimed in claim 1, comprising a step of determining the size Nₚ of the coded signal depending on a statistical distribution of the values of the digital signal.

3. The coding method as claimed in claim 2, wherein the size Nₚ of the coded signal is parameterized so as to minimize the energy consumption of a digital computing system in which the processed signals are coded by means of said coding method.

4. The coding method as claimed in claim 3, wherein the energy consumption is estimated by simulation or on the basis of an empirical model.

5. The coding method as claimed in claim 1, wherein the digital computing system implements an artificial neural network.

6. The coding method as claimed in claim 5, wherein the size Nₚ of the coded signal is parameterized independently for each layer of the artificial neural network.

7. A coding device, comprising a coder configured to execute the coding method as claimed in claim 1.

8. An integration device, configured to carry out a multiply-accumulate (MAC) operation between a first number coded by means of the coding method as claimed in claim 1 and a weighting coefficient, the device comprising a multiplier (MUL) for multiplying the weighting coefficient by the coded number, an adder (ADD) and an accumulation register (RAC) for accumulating the output signal of the multiplier (MUL).

9. An artificial neuron (N), implemented by a digital computing system, comprising an integration device configured to carry out a multiply-accumulate (MAC) operation between a first number coded by means of the coding method as claimed in claim 1 and a weighting coefficient, the device comprising a multiplier (MUL) for multiplying the weighting coefficient by the coded number, an adder (ADD) and an accumulation register (RAC) for accumulating the output signal of the multiplier (MUL), the integration device carrying out a multiply-accumulate (MAC) operation between a received signal and a synaptic coefficient, and a coding device comprising a coder configured to execute the coding method as claimed in claim 1, for coding the output signal of the integration device, the artificial neuron (N) being configured to propagate the coded signal to another artificial neuron.

10. An artificial neuron (N), implemented by a computer, comprising an integration device configured to carry out a multiply-accumulate (MAC) operation between a first number coded by means of the coding method as claimed in claim 1 and a weighting coefficient, the device comprising a multiplier (MUL) for multiplying the weighting coefficient by the coded number, an adder (ADD) and an accumulation register (RAC) for accumulating the output signal of the multiplier (MUL), the integration device carrying out a multiply-accumulate (MAC) operation between an error signal received from another artificial neuron and a synaptic coefficient, a local error computing module configured to compute a local error signal on the basis of the output signal of the integration device and a coding device comprising a coder configured to execute the coding method as claimed in claim 1, for coding the local error signal, the artificial neuron (N) being configured to back-propagate the local error signal to another artificial neuron.

11. An artificial neural network, comprising a plurality of artificial neurons as claimed in claim 9.
